(19) United States
(12) Patent Application Publication
(10) Pub. No.: US 2005/0019989 A1
(43) Pub. Date: Jan. 27, 2005

(54) Method for making a module comprising at least an electronic component

(76) Inventor: Francois Droz, La Chaux-de-Fonds (CH)

Correspondence Address: Clifford W Browning;Woodard Emhardt Naughton Moriarty & McNett, Bank One Center/Tower, 111 Monument Circle Suite 3700, Indianapolis, IN, 46204-5137, US

(21) Appl. No.: 10/496,028

(22) PCT Filed: Nov. 21, 2002
(86) PCT No.: PCT/IB02/04936

(30) Foreign Application Priority Data
Nov. 23, 2001 (CH) 2161/01

(51) Int. Cl. H01L 21/44

(52) U.S. Cl. 438/127

(57) ABSTRACT

This aim is reached by a method for manufacturing an electronic module comprising at least one electronic component (4) and a layer formed by a binder, the electronic component (4) presents a visible face on the surface of the module, characterized in that one places a frame (3) on a protection sheet (2) placed on a base plate (1). At least one electronic component (4) is then placed on the protection sheet (2) and inside the frame (3). A pressing plate (6) is leant on the outline of the frame (3) before the introduction of a binder through orifices (5) pierced in the frame (3). This binder encapsulates the electronic component (4) by filling the space defined by the frame (3), the protection sheet (2) and the pressing plate (6). After solidification of the binder, the base plate (1) and the pressing plate (6) are removed.

The present invention belongs to the field of manufacturing processes of an electronic module comprising a layer formed by a binder and at least one electronic component.

The invention concerns modules made by filling a mould with a binder, these modules including at least one electronic component. An electronic component is defined here as an element such a chip, a transponder, an integrated circuit, a capacitance, a resistor, a fuse, a battery, solar cells, a display, a fingertip controller, a switch, a keyboard, or all other similar element. The electronic component can be also an electronic circuit formed by the connection of a plurality of elements such as quoted above.

The electronic modules made like this include at least one planar face and a second face generally parallel to the first one from where flushes the visible part of the electronic component. Their outline is of any shape. Their thickness is close to the one of the highest electronic component. The components are entirely or partially embedded in a rigid insulating mass formed by a solidified binder. The module external shape is defined by the mould in which is introduced the binder during the manufacture of the module.

In general, these modules are destined to applications, which require a great mechanical sturdiness, a certain resistance to environment constraints (corrosion, pressure, temperature, humidity) and inviolability (difficulty of dismounting or of piracy). These modules can, for example, constitute means of control, of identification, of registration/restitution of sophisticated data or apparatuses components such as computers, control automates, electrical power supply blocks etc.

The subject of this invention focuses particularly on the manufacture method of these modules. It is known by those skilled in the art, modules obtained by encapsulation of electronic circuits processes where a binding is flowed in a mould containing the circuit. After hardening of the binder, the module is extracted from the mould. The shape and the size of the module are defined by those given to the mould. For example, document U.S. Pat. No. 5,416,358 describes a flat module, which includes a frame surrounding a printed circuit board on which electronic components are mounted. The frame is provided of lateral orifices destined to the injection of filling resin (binder). Each face of the frame is covered by at least one insulating sheet, which can include a decoration. The module does not include any apparent component on one of its faces. All the components are mounted on a printed circuit, which is placed in the frame in order to be encapsulated by a resin.

The documents U.S. Pat. No. 4,961,893 and FR2630843 describe a process of over molding a chip card using a mould in two parts, one fixed and one moving part, defining an impression, which gives the external shape of the card. A support sheet in insulating material is clamped between the two parts of the mould making a separation of the volume formed by the cavities of the fixed and the moving parts when the mould is closed. Electronic components are glued on the face of the support sheet directed to the fixed part of the mould. A plastic filling material is injected, through adequate orifices, in the volume delimited by the fixed part and the support sheet. The latter is then pushed against the walls of the cavity of the moving part under the pressure of the injected material. The components are then partially embedded in the mass of the filling material. During the extraction of the card from the mould, the support sheet adheres on the moving part of the mould. The faces of components previously glued on the support sheet appear then on the face of the card.

This method is particularly adapted to the manufacture of low thickness cards including at least one component presenting an access face such as a contacts module. A relatively high pressure is then necessary for the injection of the filling material in order to push the support sheet, on which are glued the components, against the inner walls of the mould.

In an embodiment of the method described above, the positioning of the components is made by air suction through orifices made in the mould in particular on the two planar faces. The application of this method needs a sophisticated mould connected to an air suction system, which requires a difficult installation.

These known processes need onerous and relatively long steps, which prevent a very large volume production of modules. Moreover, difficulties appear at the level of the electronic components holding during the preparation phases of the mould and during the flowing of the binder. In fact, some components must be placed in an accurate position on the final module, especially when a face of the component appears on one of the module faces. For example, a display, solar cells and an integrated circuit have a position determined namely by the foreseen functioning of the module.

Another method uses a positioning structure including windows in which the components are inserted. This structure is placed in the mould cavity before pouring the binder.

According to the document EP0650620, a method is described using a compressible positioning structure, which holds the electronic components between two pressing plates during the binder injection.

The methods using a positioning structure are well adapted for modules including electronic components entirely embedded in the binding mass as for example in the case of the contactless chip cards.

Some modules include electronic components from which one face must appear on the surface of the module. These cases arise for components such as a display, solar cells, keyboard keys, etc. The methods described above are difficult to apply because the binder can flow on the surface of the component, which must remain visible on the face of the module. In fact a gap can subsist between the face of the component and the bottom of the mould cavity. This gap is formed by flatness shortcomings of the component surface and the mould inner face against which the component is pressed. The binder then flows in this gap by capillarity effect, or by suction if the component is maintained in the mould by vacuum. The useful face of the concerned component is then damaged.

The aim of this invention is to avoid the drawbacks described above by offering a low cost method of manufacturing modules allowing a large volume production. This concerns in particular the positioning of the electronic components in the mould which must be maintained during the whole manufacture process of the module by guaranteeing the integrity of the visible surface of said components on one and/or the other face of the module.

This aim is reached by a method for manufacturing a module comprising at least one electronic component and a layer formed by a binder, the electronic component being partially embedded in a rigid mass formed by the solidified binder, presents a visible face on the module surface, the outer faces of said module being sensibly flat, characterized in that it includes the following steps:
placing of a protection sheet on a base plate,
placing a frame on said protection sheet, said frame defines the final shape of the module; the thickness of the frame is determined by the maximum height of the electronic component,
putting on the protection sheet and inside the frame at least one electronic component, the position of said component being maintained by adhesion on the protection sheet,
leaning a pressing plate on the outline of the frame,
introducing a binder between the protection sheet and the pressing plate through orifices provided for that purpose in the frame, said binder encapsulating the electronic component and filling the space defined by the frame, the protection sheet and the pressing plate,
solidifying the binder, said binder forming a rigid layer maintaining the electronic component,
removing the base plate and the pressing plate after solidification of the binder.

The protection sheet used in the above method consists of a plastic material film in general covered by an adhesive substance on all or part of its surface. It has the particularity to offer a provisional and non-permanent gluing of the components applied to its surface. Furthermore, this sheet applies on the surface of the component in such a way to obstruct all the residual gaps, which could let the binder pass between the protection sheet and the surface of the component. The removal of this sheet, at the end of the module manufacturing process remains easy; the adhesive layer of the film surface does not leave any trace on the component.

Another embodiment of the protection sheet is free of adhesive substance thanks to the fact that it consists of a non-absorbing sheet, for example made on rubber or silicone. The electronic component, applied on the sheet by pressure, embeds lightly in the sheet thickness, which assures the impermeability to the binder necessary for the component surface protection. This pressure is obtained with the placement of a compressible material placed on the electronic component and which comes in support on the pressing plate.

This method facilitates furthermore the manufacture of modules in important sets by allowing a superposition of the moulds. This advantage appears by the preparation of an elements stacking: base plate, protection sheet, frame, component, pressing plate, before the binder injection step.

According to a first embodiment of the method, a compressible material can be superimposed on the electronic component in order to improve its holding when its attachment on the protection sheet proves insufficient. This case occurs particularly for a relatively high weight component such as a battery or a display placed away from the module edges, respectively frame edges. Furthermore, during the manufacture in series, for practical reasons of assembly and to limit the encumbrance, the moulds are preferably arranged vertically. The component must not thus leave its position under the effect of gravity.

According to another embodiment of the method, an insulating material sheet with windows, here called positioning structure, can be placed of on the protection sheet.

The electronic components are inserted in the windows and one of the components faces is applied against the protection sheet. The windows size corresponds to the one of the components outline. This supplementary maintenance mean would be used for example, for a large number of uneven size components. In this embodiment, a compressible material as described above can also cover the set of the components in order to improve their holding in the mould.

The invention will be better understood thanks to the following detailed description referring to the attached drawings given as a non-limitative example, in which:

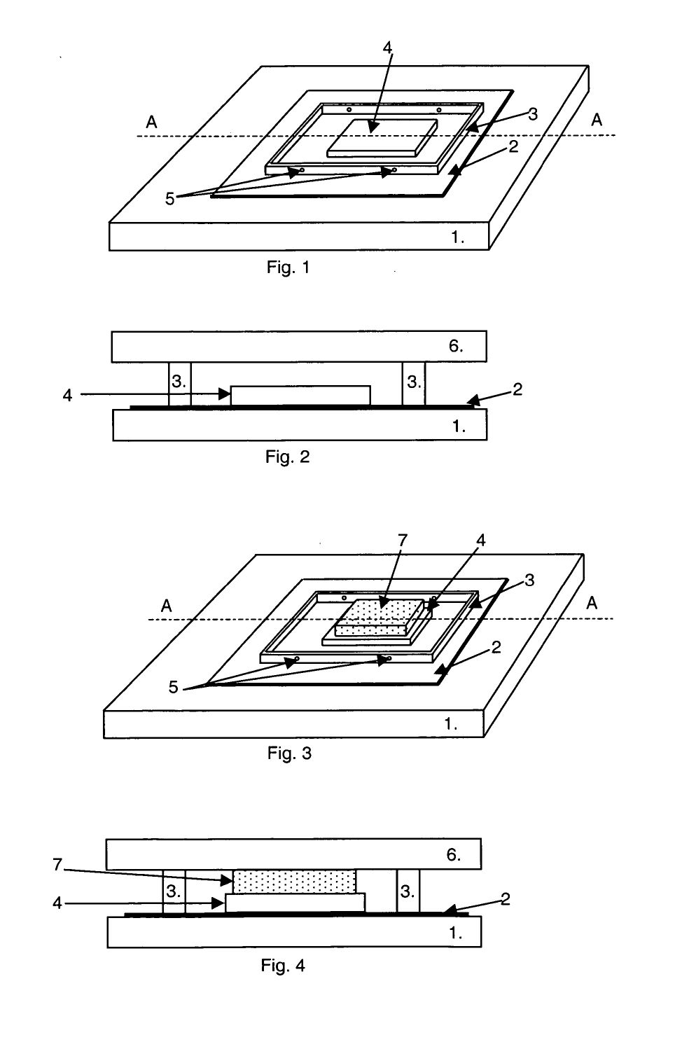

FIG. 1 represents a general view of a layout serving to the module manufacture

FIG. 2 shows a section of the layout of FIG. 1.

FIG. 3 represents a general view of a layout with a compressible material.

FIG. 4 shows a section of the layout of FIG. 2.

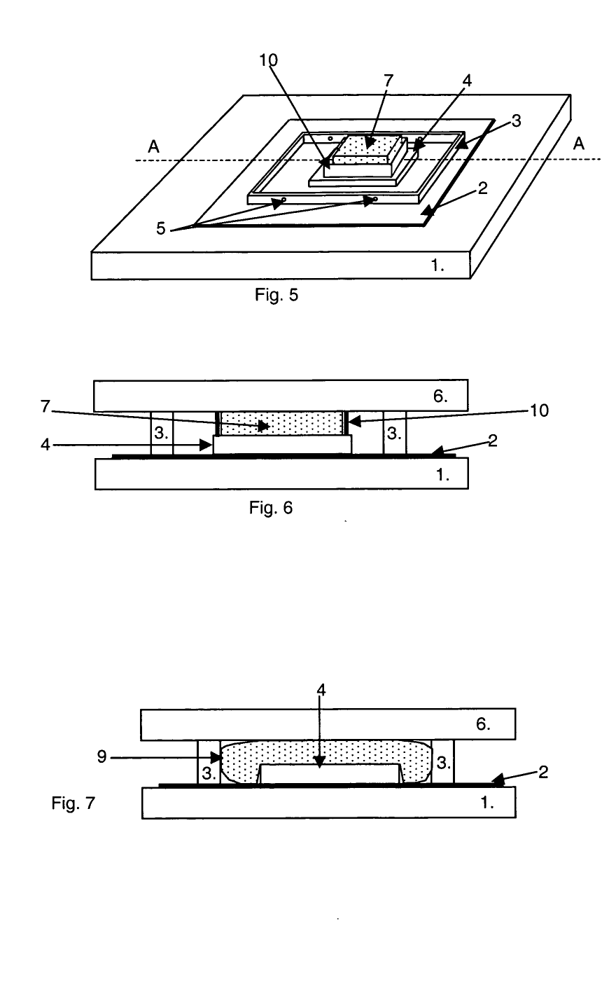

FIG. 5 represents a general view of a layout with a compressible material displaced in a semi-shell

FIG. 6 shows a section of the layout of FIG. 5.

FIG. 7 shows an embodiment of FIG. 4 with a compressible material widespread.

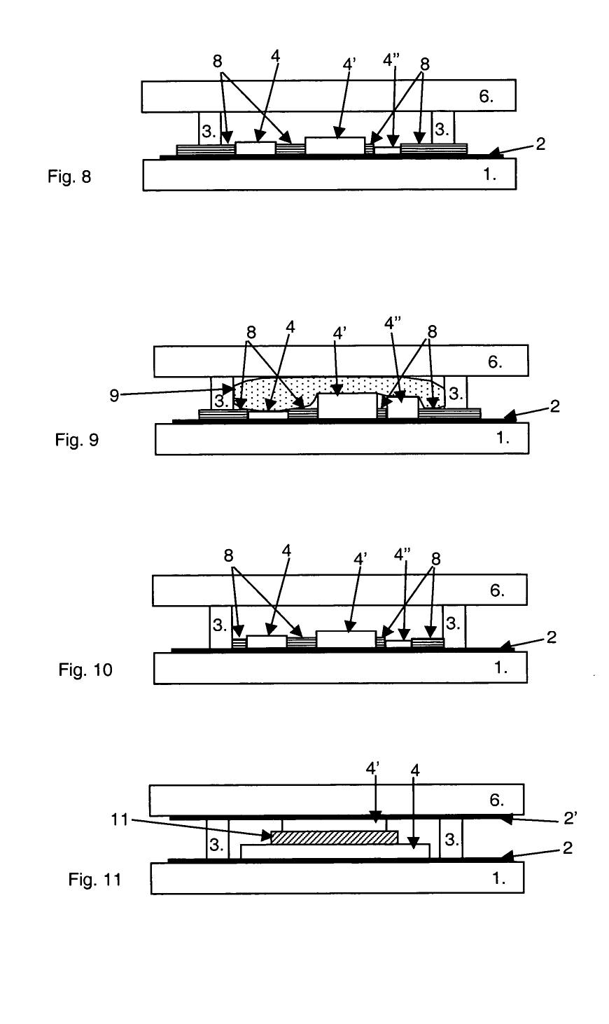

FIG. 8 shows a section of a layout including a positioning structure.

FIG. 9 shows a section of a layout including a positioning structure and a compressible material.

FIG. 10 shows a section of a layout including a positioning structure inside the frame.

FIG. 11 shows a layout with two superimposed components separated by a compressible material.

FIG. 1 shows an example of elements layout serving to the module manufacture. A protection sheet (2) is placed on a base plate (1). A frame (3) is placed on the protection sheet (2). An electronic component (4) is placed inside the frame (3) to the location predetermined by the module configuration. This component adheres to the protection sheet (2), which maintains its position during all the manufacture process phases. The frame (3) defines the final shape of the module; its thickness is at least equal to the maximum height of the component (4).

FIG. 2 is a section according to the axis A-A of the layout of FIG. 1, on which a pressing plate (6) is placed on the frame (3). The base plate (1), the frame and the pressing plate (6) constitute a mould. The binder is injected through the orifices (5) made for that purpose in the frame (3) and fills all the space around the component (4) delimited by the inner walls of the mould. The latter are formed by the protection sheet (2) covering the base plate (1), the inner walls of the frame (3) and the inner face of the pressing plate (6). In general, the thickness of the frame is greater than the height of the component in such a way it leaves a space between the latter and the pressing plate. The binder then can cover the face thus disengaged of the component.

FIG. 3 shows an embodiment of the method according to the invention in which a compressible material (7) is superimposed on the component (4). The thickness of the compressible material (7) is chosen in such a way that the total height reached by the component covered by the compressible material is either equal or greater than the thickness of the frame (3).

FIG. 4 represents a section of the layout of FIG. 3 according to the axis A-A with the pressing plate (6) exerting a pressure on the component (4) through the compressible material (7). The maintenance of the electronic component (4) in the mould is then improved. The compressible material (7) is constituted by a foam plastic material, a waved sheet or other material having adequate elasticity. The binder introduced in the mould is absorbed by this in general porous material like the foam for example, and fills the free space in the mould.

FIG. 5 shows an embodiment of FIG. 3 where the compressible material (7) is placed inside a semi-shell (10) that is placed on the electronic component (4).

FIG. 6 represents a section of the layout of FIG. 5 according to the axis A-A with the pressing plate (6). The height of the semi-shell walls (10) corresponds to the height of the space separating the electronic component (4) from the pressing plate (6). A pressure is exerted on the component (4) by the pressing plate (6) and through the compressible material (7) whose thickness is greater than the height of the semi-shell walls (10). The binder introduced in the mould is spread in all the free space delimited by walls of the frame (3), the base (1) and pressing (6) plates and the walls of the semi-shell (10). The binder thus does not penetrate inside the semi-shell (10) where the compressible material (7) is lodged. After the hardening of the binder, the base (1) and pressing (6) plates are dismounted and the compressible material (7) is removed from the inside of the semi-shell (10). The module so obtained includes on one of its faces a cavity formed by the semi-shell (10). This cavity can serve for housing a battery for example, the bottom of the semi-shell includes openings to let pass contacts placed on the internal face of the electronic component (4).

FIG. 7 represents a case where the size of the compressible material (9) is chosen in order to correspond to the one of the inner outline of the frame (3).

FIG. 8 shows an embodiment where several electronic components (4, 4′, 4″) of small size are housed in windows formed in an insulating material sheet (8) called positioning structure. This structure (8), placed on the protection sheet (2) groups components (4, 4′, 4″) in a well-defined position by preventing their dispersion during the injection of the binder in the mould. The surface of this positioning structure (8) occupies all or part of the surface of the protection sheet (2), the frame (3) being placed on the positioning structure (8). The external surface of the latter can carry a decoration appearing on the finished module. When the positioning structure (8) exceeds the external outline of the frame (3), a finishing step of the module outline is necessary by stamping it for example.

FIG. 9 shows an embodiment of FIG. 6 where the components (4, 4′, 4″) are covered by a compressible material (9) occupying the whole surface delimited with the inner outline of the frame (3). The components (4, 4′, 4″) maintaining against the protection sheet (2) is thus improved by the pressure exerted on the pressing plate (6) acting on the compressible material (9).

FIG. 10 shows an embodiment where the positioning structure (8) occupies all or part of the surface delimited by the inner outline of the frame (3); the latter being placed on the protection sheet (2). In an embodiment not illustrated, a compressible material can cover the electronic components in order to improve the maintenance of the set components—positioning structure through the pressure on the pressing plate (6).

FIG. 11 shows a layout for the manufacturing of a module including electronic components (4, 4′) whose face must appear on each face of the module. A first protection sheet (2) is placed on the base plate (1). The frame (3) is placed on the protection sheet (2). Inside the frame (3) a first component (4) is positioned on which the compressible material (11) is superimposed. A second component (4′) is positioned on the compressible material (11) on which a second protection sheet (2′) is placed. This sheet has a surface at least equivalent to the one delimited by the external outline of the frame (3) in such a way to avoid the flowing of binder on the component face (4′), which must appear on the module face. The total height reached by the superimposition of the components (4, 4′) and the compressible material (11) exceeds the frame thickness. The compressible material thickness is thus chosen in order to assure sufficient pressure on the set with the pressing plate (6) that closes the mould.

Another embodiment not illustrated of the method consists in:
placing the frame (3) on the base plate (1),
putting the protection sheet (2) inside the frame (3), the surface of the protection sheet (2) occupies all or part of the surface delimited by the inner outline of the frame (3). The protection sheet (2) adheres to the base plate for example by the mean of glue or by electrostatic attraction.
putting on the protection sheet at least one electronic component (4)
leaning the pressing plate (6) on the outline of the frame in order to close the mould.

The binder is then introduced through the orifices (5) of the frame (3), and then solidified.

In order to prevent the binder infiltration on the component useful face which must appear on the surface of the module, the size of the protection sheet must be equal or greater than the one of the component, the latter being entirely placed on the protection sheet.

This embodiment can apply for example in the case of a module where the component visible surface must be in a light recess compared with the surface of the module. This recess is equivalent to the thickness of the protection sheet placed inside the frame without therefore occupying the whole inner surface of said frame.

After the solidification of the binder, the mould is dismounted by removal of the base (1) and pressing (6) plates. The removal of the frame (3) is optional and depends on the desired shape and/or the finish of the module. The protection sheet (2) is withdrawn at last, either before the finish of the module faces, or after the assembly of the module in an apparatus for example. This sheet can serve as protection of the component during the manipulations of the module. For example, it prevents stripes on the transparent surface of a display.

A facultative final step of the manufacture process of the modules after their removal from the mould consists in applying a plastic material film on one or each face of the module. This film, serving as decoration, includes the necessary windows to let appear the components useful faces such as a display, solar cells, keys, etc.

1-18. (canceled).

19. Method for manufacturing a module comprising at least one electronic component and a layer formed by a binder, the electronic component being partially embedded in a rigid mass formed by the solidified binder, presents a visible face on the module surface, the outer faces of said module being sensibly flat, characterized in that it includes the following steps:
placing of a protection sheet on a base plate,
placing a frame on said protection sheet, said frame defines the final shape of the module; the thickness of the frame is determined by the maximum height of the electronic component,
putting on the protection sheet and inside the frame at least one electronic component, the position of said component being maintained by adhesion on the protection sheet,
superimposing a compressible material on the electronic component to cover all or part of said electronic component,
leaning a pressing plate on the outline of the frame, said plate exerting a pressure on the compressible material,
introducing a binder between the protection sheet and the pressing plate through orifices provided for that purpose in the frame, said binder encapsulating the electronic component and filling the space defined by the frame, the protection sheet and the pressing plate,
solidifying the binder, said binder forming a rigid layer maintaining the electronic component,
removing the base plate and the pressing plate after solidification of the binder.

20. Method for manufacturing according to claim 19, characterized in that the protection sheet includes an adhesive substance on all or part of its surface, the electronic component being placed on the adhesive zones of the protection sheet surface.

21. Method for manufacturing according to claim 19, characterized in that the frame is placed on the base plate, the protection sheet is placed inside the frame, said sheet, occupying all or part of the surface delimited by the inner outline of the frame, is maintained by adhesion on the base plate, the electronic component is entirely placed on the protection sheet, said sheet maintains the component by adhesion.

22. Method for manufacturing according to claim 19, characterized in that the thickness of the compressible material is determined in such a way to make the pressure applied on the pressing plate act on the electronic component.

23. Method for manufacturing according to claim 19, characterized in that the compressible material is placed inside a semi-shell, said semi-shell is placed on the electronic component, the height of the semi-shell walls corresponding to the height of the space separating the electronic component from the pressing plate, the binder introduced by the orifices of the frame spreads in free space delimited by the frame walls, the base and pressing plates and the semi-shell walls, said binder does not penetrate inside the semi-shell where is the compressible material, after solidification of the binder, the base and pressing plates are dismounted and the compressible material is removed from the inside of the semi-shell.

24. Method for manufacturing according to claim 22, characterized in that the compressible material occupies the whole surface delimited by the inner outline of the frame.

25. Method for manufacturing according to claim 19, characterized in that a positioning structure is placed on the protection sheet, said positioning structure occupies all or part of the surface of the protection sheet, said structure includes at least one window in which is housed the electronic component, said component is maintained by the protection sheet and the positioning structure.

26. Method for manufacturing according to claim 25, characterized in that the frame is placed on the positioning structure and in that a final step, after solidification of the binder, consists in adjusting the outline of said placement structure to the final module size.

27. Method for manufacturing according to claim 25, characterized in that the positioning structure occupies all or part of the surface of the protection sheet delimited by the inner outline of the frame, said frame being placed on the protection sheet.

28. Method for manufacturing according to claim 25, characterized in that the frame is integral with the positioning structure, the set thus formed constituting a cavity, the bottom of said cavity corresponding to the positioning structure and the side walls corresponding to the frame.

29. Method for manufacturing according to claim 25, characterized in that the external face of the positioning structure is used as decoration.

30. Method for manufacturing according to claim 25, characterized in that a compressible material is superimposed on the positioning structure in which is housed the electronic component.

31. Manufacture process of an electronic module, according to claim 19, characterized in that a second electronic component is superimposed on the first electronic component, said components are separated by a compressible material, the second component is covered by a second protection sheet in support on the pressing plate, said second sheet having a surface at least equivalent to the one delimited by the external outline of the frame.

32. Method for manufacturing according to claim 19, characterized in that the frame is removed after solidification of the binder and the opening of the base and pressing plates.

33. Method for manufacturing of an electronic module according to claim 19, characterized in that the frame is a part of the module and is kept after solidification of the binder and the opening of the base and pressing plates.

34. Method for manufacturing according to claim 19, characterized in that the protection sheet is removed only during the final use of the module, said sheet protects the electronic component during module manipulations.

35. Method for manufacturing of an electronic module, according to claim 19, characterized in that a plastic material film is applied on one or each face of the finished module, said film, serving as decoration, includes the windows necessary to let appear the electronic components useful faces.
